(19) United States
(12) Patent Application Publication
(10) Pub. No.: US 2012/0325196 A1
(43) Pub. Date: Dec. 27, 2012

(54) METHOD FOR MANUFACTURING SILICON CARBIDE SUBSTRATE

(75) Inventors: Kyoko OKITA, Itami-shi (JP); Shinsuke Fujiwara, Itami-shi (JP)

(73) Assignee: SUMITOMO ELECTRIC INDUSTRIES, LTD., Osaka-shi (JP)

(21) Appl. No.: 13/530,486

(22) Filed: Jun. 22, 2012

Related U.S. Application Data
(60) Provisional application No. 61/500,210, filed on Jun. 23, 2011.

(30) Foreign Application Priority Data
Jun. 23, 2011 (JP) 2011-139145

(51) Int. Cl. H01L 21/304

(52) U.S. Cl. 125/2

(57) ABSTRACT

A method for manufacturing a silicon carbide substrate includes the steps of preparing an ingot of single crystal silicon carbide, obtaining a silicon carbide substrate by cutting the ingot, and forming a chamfer portion in a region including an outer peripheral surface of the silicon carbide substrate. In the step of obtaining the silicon carbide substrate, the ingot is cut such that a main surface of the silicon carbide substrate forms an angle of not less than 10° with respect to a {0001} plane.

### BACKGROUND OF THE INVENTION

1. Field of the Invention

The present invention relates to a method for manufacturing a silicon carbide substrate, and more particularly to a method for manufacturing a silicon carbide substrate capable of suppressing occurrence of chipping during formation of a chamfer portion.

2. Description of the Background Art

In recent years, in order to achieve a higher breakdown voltage and lower loss of a semiconductor device, use thereof in an environment at high temperature and the like, silicon carbide has increasingly been adopted as a material for forming a semiconductor device. Silicon carbide is a wide band-gap semiconductor greater in band gap than silicon conventionally widely used as a material for forming a semiconductor device. Therefore, by adopting silicon carbide as a material for forming a semiconductor device, a higher breakdown voltage, a lower ON resistance of a semiconductor device and the like can be achieved. In addition, a semiconductor device adopting silicon carbide as a material is also more advantageous than a semiconductor device adopting silicon as a material in that deterioration in its characteristics at the time when it is used in an environment at high temperature is less.

A semiconductor device using silicon carbide as a material is manufactured, for example, by forming an epitaxial growth layer on a silicon carbide substrate, forming in the epitaxial growth layer a region in which a desired impurity has been introduced, and forming an electrode. The silicon carbide substrate is generally manufactured by cutting (slicing) a crystal (an ingot) of silicon carbide. Silicon carbide, however, has extremely high hardness and hence cutting thereof is not easy. Therefore, a method for cutting a silicon carbide crystal has variously been studied, and various methods have been proposed (see, for example, Japanese Patent Laying-Open No. 2009-61528).

In a silicon carbide substrate fabricated as described above, a chamfer portion is preferably formed in a region including an outer peripheral surface to improve ease of subsequent handling. However, if a chamfer portion is formed without taking any measures, chipping occurs in the chamfer portion.

### SUMMARY OF THE INVENTION

The present invention was made to solve such a problem, and one object of the present invention is to provide a method for manufacturing a silicon carbide substrate capable of suppressing occurrence of chipping during formation of a chamfer portion.

A method for manufacturing a silicon carbide substrate in accordance with the present invention includes the steps of: preparing a crystal of single crystal silicon carbide, obtaining a substrate by cutting the crystal, and forming a chamfer portion in a region including an outer peripheral surface of the substrate. In the step of obtaining the substrate, the crystal is cut such that a main surface of the substrate forms an angle of not less than 10° with respect to a {0001} plane.

The present inventor conducted detailed studies of approaches for suppressing occurrence of chipping during formation of a chamfer portion, obtained the following findings, and then derived the present invention.

Namely, the present inventor focused on a place of occurrence of chipping and a plane orientation of a substrate main surface, and studied frequency of occurrence of chipping. As a result, the present inventor found that chipping is likely to occur at a boundary portion between a main surface on a silicon plane side of a silicon carbide substrate and a chamfer portion connected to the main surface. Then, the present inventor found that, when a substrate is obtained by cutting a silicon carbide crystal, the occurrence of chipping described above is clearly suppressed in a substrate obtained by cutting the above crystal such that a main surface of the substrate forms an angle of not less than a predetermined value, more specifically, an angle of not less than 10°, with respect to the {0001} plane.

In the method for manufacturing the silicon carbide substrate in accordance with the present invention, in the step of obtaining the substrate, the crystal is cut such that a main surface of the substrate forms an angle of not less than 10° with respect to the {0001} plane. As a result, according to the method for manufacturing the silicon carbide substrate in accordance with the present invention, occurrence of chipping during formation of a chamfer portion can be suppressed.

It is to be noted that a hexagonal silicon carbide single crystal has a (0001) plane as a silicon plane having silicon atoms arranged in a surface thereof, and a (000-1) plane as a carbon plane formed opposite to the (0001) plane and having carbon atoms arranged in a surface thereof. In addition, the main surface on the silicon plane side described above refers to a main surface on a side close to the silicon plane.

In the method for manufacturing the silicon carbide substrate, in the step of forming the chamfer portion, the chamfer portion may be formed such that a surface of a region connected to the main surface on the silicon plane side of the substrate in the chamfer portion forms an angle of not less than 20° with respect to the (0001) plane.

According to the studies by the present inventor, if the surface of the region connected to the main surface on the silicon plane side of the substrate in the chamfer portion forms a small angle of less than 20° with respect to the (0001) plane, chipping is likely to occur. Therefore, occurrence of chipping can be suppressed by forming the chamfer portion such that the surface of the region connected to the main surface on the silicon plane side of the substrate in the chamfer portion forms an angle of not less than 20° with respect to the (0001) plane.

In the method for manufacturing the silicon carbide substrate, in the step of forming the chamfer portion, the chamfer portion may be formed such that, if 0° represents a chamfer angle and L mm represents a chamfer width in the chamfer portion formed to be connected to the main surface on the silicon plane side of the substrate, θ/L is more than 30 and less than 200.

Chamfer processing is often performed by supplying a liquid such as a polishing liquid to an outer peripheral surface of a substrate and at the same time bringing a grindstone into contact with the outer peripheral surface and rotating the substrate in a circumferential direction. On this occasion, if the chamfer width is small, the polishing liquid is not fully supplied to a portion being processed, and chipping is likely to occur. On the other hand, if the chamfer angle is increased, the occurrence of chipping is suppressed. Considering influences of both the chamfer width and the chamfer angle, occurrence of chipping can be effectively suppressed by setting θ/L to be more than 30. On the other hand, if θ/L is not less than 200, the surface of the chamfer portion is almost perpendicular to the main surface, which may cause a problem that chipping is likely to occur. Therefore, preferably, θ/L is more than 30 and less than 200.

Here, the chamfer angle refers to a more acute angle of angles formed between a flat surface including a main surface and a curved surface including a chamfer portion connected thereto. Further, the chamfer width refers to a length in a radial direction of a region processed by chamfer processing.

In the method for manufacturing the silicon carbide substrate, in the step of forming the chamfer portion, the chamfer portion may be formed such that a chamfer radius is not less than 0.1 mm and not more than 0.3 mm.

If the chamfer radius is less than 0.1 mm, an outer peripheral portion is pointed, which may cause a problem that chipping is likely to occur. On the other hand, if the chamfer radius is more than 0.3 mm, the outer peripheral surface (outer peripheral curved surface) is almost perpendicular to an inclined surface connected to the outer peripheral surface, which may cause a problem that chipping is likely to occur. Therefore, preferably, the chamfer radius is not less than 0.1 mm and not more than 0.3 mm. It is to be noted that the chamfer radius refers to a radius of curvature of a curved surface formed at a substrate outer peripheral surface in a cross section in a thickness direction of a substrate subjected to chamfer processing.

In the method for manufacturing the silicon carbide substrate, in the step of forming the chamfer portion, the chamfer portion may be formed in the region including the outer peripheral surface having a concave shape on the silicon plane side of the substrate, in the substrate.

When the chamfer portion is formed in the region having a concave shape at the main surface on the silicon plane side, the above chipping is particularly likely to occur. The method for manufacturing the silicon carbide substrate in accordance with the present invention, which can suppress occurrence of chipping, is particularly suitable when chamfer processing is performed in such a situation where chipping is particularly likely to occur.

In the method for manufacturing the silicon carbide substrate, in the step of forming the chamfer portion, the chamfer portion may be formed such that variation in chamfer width is within 100 μm. Variation in chamfer width causes warpage of a substrate. By setting the variation to be within 100 μm, warpage of a manufactured silicon carbide substrate can be reduced. It is to be noted that the variation in chamfer width refers to a difference between the maximum value and the minimum value of the chamfer width.

As is clear from the description above, according to the method for manufacturing the silicon carbide substrate in accordance with the present invention, a method for manufacturing a silicon carbide substrate capable of suppressing occurrence of chipping during formation of a chamfer portion can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic perspective view showing an ingot of single crystal silicon carbide.

FIG. 2 is a schematic plan view showing a method for cutting the ingot.

FIG. 3 is a schematic perspective view showing a substrate obtained by cutting the ingot.

FIG. 4 is a schematic partial cross sectional view showing a shape of a chamfer portion of the substrate.

FIG. 5 is a schematic cross sectional view showing the relation between a deformed state of the substrate and an area in which formation of a chamfer portion is desirable.

FIG. 6 is a schematic cross sectional view showing the relation between a deformed state of the substrate and an area in which formation of a chamfer portion is desirable.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual orientation, a collective orientation, an individual plane, and a collective plane are herein shown in [ ], < >, ( ) and { }, respectively. Moreover, in terms of crystallography, a negative index should be denoted by a number with a bar “-” thereabove, however, a negative sign herein precedes a number.

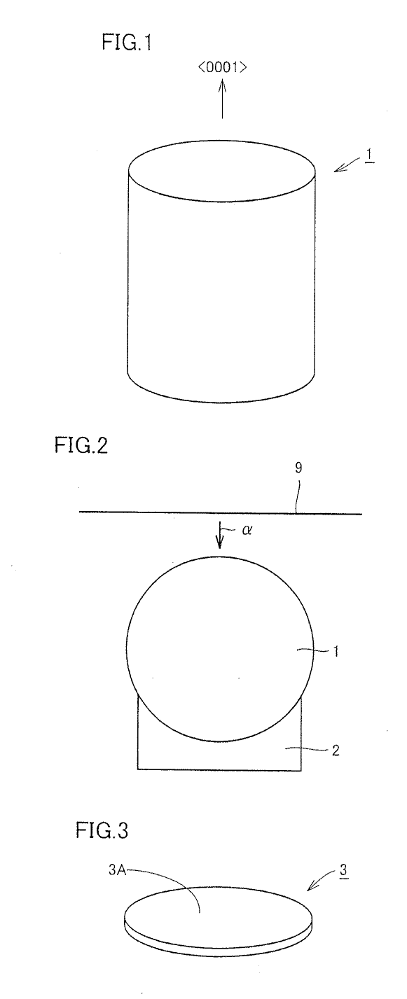

Initially, a method for manufacturing a silicon carbide substrate in one embodiment of the present invention will be described. Referring to FIG. 1, in the method for manufacturing a silicon carbide substrate in the present embodiment, initially, the step of preparing a crystal (an ingot) of single crystal silicon carbide is performed. Specifically, for example with a sublimation method described below, an ingot of single crystal silicon carbide is fabricated. Namely, a seed crystal composed of single crystal silicon carbide and source material powder composed of silicon carbide are initially placed in a container composed of graphite. Then, the source material powder is heated, and thereby silicon carbide is sublimated and recrystallized on the seed crystal. On this occasion, recrystallization proceeds while a desired impurity such as nitrogen is being introduced. Thus, an ingot 1 of single crystal silicon carbide shown in FIG. 1 is obtained. Here, by setting a direction of growth of ingot 1 to a <0001> direction as shown in FIG. 1, ingot 1 can be efficiently fabricated.

Next, a substrate is fabricated by cutting fabricated ingot 1. Specifically, referring to FIG. 2, initially, fabricated ingot 1 in the shape of a pillar (a column) is set such that a portion of its side surface is supported by a support 2. Then, a wire 9 running in a direction along a direction of a diameter of ingot 1 comes closer to ingot 1 along a cutting direction a which is a direction perpendicular to the running direction, so that wire 9 and ingot 1 come in contact with each other. Then, as wire 9 continues to move along cutting direction α, ingot 1 is cut. Thus, a silicon carbide substrate 3 shown in FIG. 3 is obtained. On this occasion, ingot 1 is cut such that a main surface 3A of silicon carbide substrate 3 forms an angle of not less than 10° with respect to a {0001} plane of a silicon carbide single crystal constituting silicon carbide substrate 3.

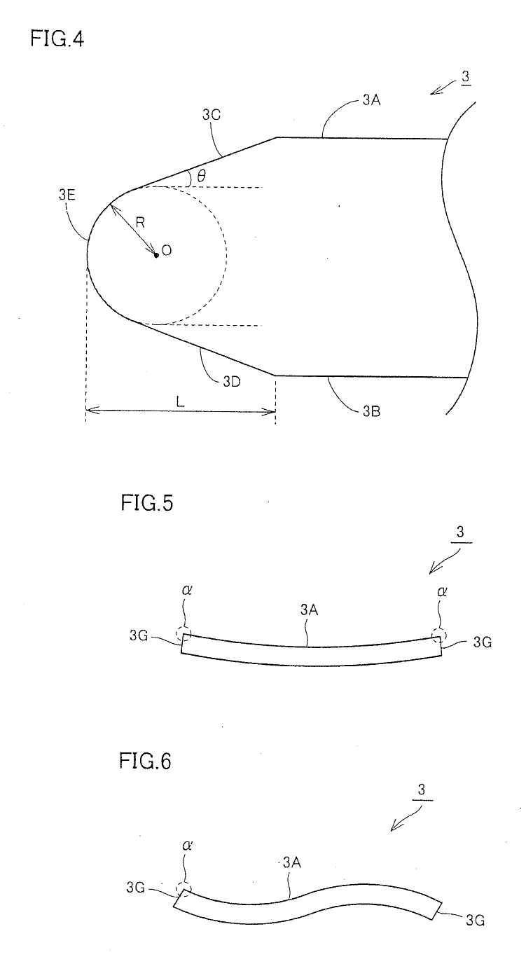

Next, chamfer processing for forming a chamfer portion in a region including an outer peripheral surface of obtained silicon carbide substrate 3 is performed. More specifically, referring to FIG. 4, for example, a chamfer portion is formed in a region including an outer peripheral surface of silicon carbide substrate 3 obtained by cutting (slicing) ingot 1 as described above, the chamfer portion including a first inclined surface 3C which is connected to one main surface 3A as a main surface on a silicon plane side and has a shape of a conical surface inclined to reduce the thickness of silicon carbide substrate 3, a second inclined surface 3D which is connected to the other main surface 3B as a main surface on a carbon plane side and has a shape of a conical surface inclined to reduce the thickness of silicon carbide substrate 3, and an outer peripheral curved surface 3E which has a shape of a curved surface (a shape of a toroidal surface) connecting first inclined surface 3C and second inclined surface 3D. Thereafter, main surfaces 3A, 3B of silicon carbide substrate 3 are planarized for example by polishing, and thereby silicon carbide substrate 3 in the present embodiment is completed.

In the method for manufacturing the silicon carbide substrate in the present embodiment, ingot 1 is cut such that main surface 3A of silicon carbide substrate 3 forms an angle of not less than 10° with respect to the {0001} plane. Therefore, occurrence of chipping is suppressed at a boundary portion between main surface 3A on the silicon plane side and first inclined surface 3C, where chipping is likely to occur during the chamfer processing.

Further, in the method for manufacturing the silicon carbide substrate in the present embodiment, when the chamfer processing is performed, the chamfer portion is preferably formed such that first inclined surface 3C as a surface of a region connected to main surface 3A on the silicon plane side of silicon carbide substrate 3 in the chamfer portion forms an angle of not less than 20° with respect to a (0001) plane. Thereby, occurrence of chipping can be further suppressed.

Furthermore, in the method for manufacturing the silicon carbide substrate in the present embodiment, when the chamfer processing is performed, referring to FIG. 4, the chamfer portion is preferably formed such that, if 0° represents a chamfer angle and L mm represents a chamfer width in the chamfer portion formed to be connected to main surface 3A on the silicon plane side of silicon carbide substrate 3, θ/L is more than 30 and less than 200. Thereby, occurrence of chipping can be further suppressed.

Further, in the method for manufacturing the silicon carbide substrate in the present embodiment, when the chamfer processing is performed, referring to FIG. 4, the chamfer portion is preferably formed such that a chamfer radius R is not less than 0.1 mm and not more than 0.3 mm. Thereby, occurrence of chipping can be further suppressed. It is to be noted that O in FIG. 4 represents the center of curvature of a curved surface formed at a substrate outer peripheral surface in a cross section in a thickness direction of silicon carbide substrate 3 subjected to the chamfer processing.

Furthermore, in the method for manufacturing the silicon carbide substrate in the present embodiment, when the chamfer processing is performed, the chamfer portion may be formed in the region including the outer peripheral surface having a concave shape at main surface 3A on the silicon plane side of silicon carbide substrate 3, in silicon carbide substrate 3. According to the method for manufacturing the silicon carbide substrate in the present embodiment, occurrence of chipping can be suppressed even under such conditions where chipping is likely to occur.

More specifically, silicon carbide substrate 3 can be deformed into various shapes, depending on the influence of conditions for cutting ingot 1 and the like. For example, when entire silicon carbide substrate 3 is deformed into an arc shape as shown in FIG. 5, the chamfer portion is preferably formed in at least a region including an outer peripheral surface 3G having a concave shape at main surface 3A on the silicon plane side, that is, each of regions a on the right and left sides in FIG. 5. Further, when silicon carbide substrate 3 is deformed into a wave shape as shown in FIG. 6, the chamfer portion is preferably formed in at least region α including outer peripheral surface 3G having a concave shape at main surface 3A on the silicon plane side, that is, region α on the left side in FIG. 6. On this occasion, the chamfer portion may be formed not only in region α in FIGS. 5 and 6 where chipping is likely to occur, but also in another region including outer peripheral surface 3G (i.e., region along outer peripheral surface 3G other than region α), and the chamfer portion may be formed over the entire periphery including region α.

Furthermore, in the method for manufacturing the silicon carbide substrate in the present embodiment, when the chamfer processing is performed, the chamfer portion is preferably formed such that variation in chamfer width L is within 100 μm over the entire periphery. Thereby, warpage of silicon carbide substrate 3 can be reduced.

### EXAMPLE

An experiment was conducted to investigate the relation between an angle formed between a substrate main surface and the (0001) plane and occurrence of chipping when chamfer processing was performed on a silicon carbide substrate. A procedure of the experiment was as follows.

Initially, a silicon carbide substrate was fabricated by preparing an ingot and slicing it by the same method as that for the above embodiment. On this occasion, the ingot was sliced such that a main surface on the silicon plane side of the silicon carbide substrate had an angle with respect to the (0001) plane, that is, an off angle from the (0001) plane, in the range of 0° to 80°. In addition, three off orientations, that is, a <10-10> direction, a <11-20> direction, and a <31-10> direction, were adopted. Then, chamfer processing was performed on the fabricated silicon carbide substrate to form a chamfer portion in a shape having chamfer angle θ of 25°, chamfer length L of 0.2 mm, and a chamfer radius of 0.2 mm. Further, an electrodeposited grindstone having a diamond grain size of #600 was used for the chamfer processing. After the chamfer processing was completed, whether or not chipping occurred was investigated. Tables 1 to 3 show results of the experiment.

TABLE 1

| | Off Angle from (0001) Plane | | | | | | | | | |
|---|---|---|---|---|---|---|---|---|---|---|
| | 0° | 5° | 10° | 20° | 30° | 40° | 50° | 60° | 70° | 80° |
| Occurrence of | Yes | Yes | No | No | No | No | No | No | No | No |
| Chipping | | | | | | | | | | |

TABLE 2

| | Off Angle from (0001) Plane | | | | | | | | | |
|---|---|---|---|---|---|---|---|---|---|---|
| | 0° | 5° | 10° | 20° | 30° | 40° | 50° | 60° | 70° | 80° |
| Occurrence of | Yes | Yes | No | No | No | No | No | No | No | No |
| Chipping | | | | | | | | | | |

TABLE 3

| | Off Angle from (0001) Plane | | | | | | | | | |
|---|---|---|---|---|---|---|---|---|---|---|
| | 0° | 5° | 10° | 20° | 30° | 40° | 50° | 60° | 70° | 80° |
| Occurrence of | Yes | Yes | No | No | No | No | No | No | No | No |
| Chipping | | | | | | | | | | |

As shown in Tables 1 to 3, irrespective of off orientation, chipping occurred when the off angle from the (0001) plane was 0° and 5°, whereas no chipping occurred when the off angle from the (0001) plane was not less than 10°, more specifically, not less than 10° and not more than 80°. Thus, it was confirmed that, when chamfer processing is performed on a silicon carbide substrate, occurrence of chipping can be suppressed by setting the angle formed between the substrate main surface and the (0001) plane to be not less than 10°.

The method for manufacturing the silicon carbide substrate in accordance with the present invention is particularly advantageously applicable to manufacturing of a silicon carbide substrate required to suppress occurrence of chipping during formation of a chamfer portion.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a crystal of single crystal silicon carbide;
obtaining a substrate by cutting said crystal; and
forming a chamfer portion in a region including an outer peripheral surface of said substrate,
in the step of obtaining said substrate, said crystal being cut such that a main surface of said substrate forms an angle of not less than 10° with respect to a {0001} plane.

2. The method for manufacturing the silicon carbide substrate according to claim 1, wherein, in the step of forming said chamfer portion, said chamfer portion is formed such that a surface of a region connected to the main surface on a silicon plane side of said substrate in said chamfer portion forms an angle of not less than 20° with respect to a (0001) plane.

3. The method for manufacturing the silicon carbide substrate according to claim 1, wherein, in the step of forming said chamfer portion, said chamfer portion is formed such that, if θ° represents a chamfer angle and L mm represents a chamfer width in said chamfer portion formed to be connected to the main surface on a silicon plane side of said substrate, θ/L is more than 30 and less than 200.

4. The method for manufacturing the silicon carbide substrate according to claim 1, wherein, in the step of forming said chamfer portion, said chamfer portion is formed such that a chamfer radius is not less than 0.1 mm and not more than 0.3 mm.

5. The method for manufacturing the silicon carbide substrate according to claim 1, wherein, in the step of forming said chamfer portion, said chamfer portion is formed in the region including the outer peripheral surface having a concave shape on a silicon plane side of said substrate, in said substrate.

6. The method for manufacturing the silicon carbide substrate according to claim 1, wherein, in the step of forming said chamfer portion, said chamfer portion is formed such that variation in chamfer width is within 100 μm.
